(19) United States
(12) Patent Application Publication
(10) Pub. No.: US 2012/0018861 A1
(43) Pub. Date: Jan. 26, 2012

(54) TAPE CARRIER SUBSTRATE

(76) Inventors: Yukihiro KOZAKA, Kyoto (JP); Hiroyuki Imamura, Osaka (JP)

(21) Appl. No.: 13/190,042

(22) Filed: Jul. 25, 2011

(30) Foreign Application Priority Data
Jul. 26, 2010 (JP) 2010-167335

(51) Int. Cl. H01L 23/495

(52) U.S. Cl. 257/668; 257/E23.031

(57) ABSTRACT

A tape carrier substrate includes: a tape carrier base 1; a first terminal section 2A including a plurality of first terminals 2a arranged with one another in a first direction W; a second terminal section 2B including a plurality of second terminals 2b; and first and second conductive wires 3a and 3b. A plurality of slits 7 arranged with one another in the first direction are provided in the tape carrier base. An interval between one of the plurality of slits placed at one end in the first direction and a corresponding end of the tape carrier base in the first direction and an interval between another one of the plurality of slits placed at the other end in the first direction and a corresponding end of the tape carrier base in the first direction are greater than an interval between adjacent ones of the plurality of slits.

### CROSS-REFERENCE TO RELATED APPLICATION

This application claims priority to Japanese Patent Application No. 2010-167335 filed on Jul. 26, 2010, the disclosure of which including the specification, the drawings, and the claims is hereby incorporated by reference in its entirety.

### BACKGROUND

The present invention relates to a tape carrier substrate.

Tape automated bonding (TAB) is a conventional method for mounting semiconductor elements. TAB is a technique for electrically connecting conductive wires (leads) of a tape-shaped, flexible tape carrier substrate with terminals of semiconductor elements with protruding electrodes (bumps) therebetween. A semiconductor device, or a tape carrier package (TCP), including a semiconductor element mounted on a tape carrier substrate is mainly used as a driver mounted on a panel of a flat panel display.

A conventional semiconductor device will be described with reference to FIGS. 10-11. FIG. 10 is a plan view showing a configuration of a conventional semiconductor device. FIG. 11 is a cross-sectional view showing a configuration of the conventional semiconductor device. FIG. 11 does not show a metal plate for the sake of simplicity.

As shown in FIG. 10, the conventional semiconductor device includes a tape carrier substrate, a semiconductor element 108, and a metal plate 111.

As shown in FIG. 10, the tape carrier substrate includes a tape carrier base 101, an input terminal section 102A including input terminals 102a, an output terminal section 102B including output terminals 102b, an input wire section 103A including input conductive wires (see 103a in FIG. 11), an output wire section 103B including output conductive wires (see 103b in FIG. 11), an input lead section (see 104A in FIG. 11) including input inner leads (see 104a in FIG. 11), an output lead section (see 104B in FIG. 11) including output inner leads (see 104b in FIG. 11), and an insulating film 105.

As shown in FIG. 11, the tape carrier base 101 includes a device hole 106 provided therein. The semiconductor element 108 is placed in the device hole 106.

As shown in FIG. 10, the tape carrier base 101 includes a plurality of slits 107 provided therein. The plurality of slits 107 are arranged with one another in the first direction W. Each of the plurality of slits 107 extends in the second direction L perpendicular to the first direction W. The interval s21 and the interval s2r are equal to the interval s1 (s21=s2r=s1). The interval s21 is the interval between one of the plurality of slits 107 placed at one end (the left end in FIG. 10) in the first direction W and the corresponding end of the tape carrier base 101 in the first direction W (the left end in FIG. 10). The interval s2r is the interval between another one of the plurality of slits 107 placed at the other end (the right end in FIG. 10) in the first direction W and the corresponding end of the tape carrier base 101 in the first direction W (the right end in FIG. 10). The interval s1 is the interval between adjacent ones of the plurality of slits 107.

As shown in FIGS. 10 and 11, the input terminal section 102A includes a plurality of input terminals 102a. The input terminals 102a are provided on the tape carrier base 101. The plurality of input terminals 102a are arranged with one another in the first direction W. The output terminal section 102B includes a plurality of output terminals 102b. The output terminals 102b are provided on the tape carrier base 101. The plurality of output terminals 102b are arranged with one another in the first direction W.

As shown in FIG. 11, the input wire section 103A includes input conductive wires 103a connected to the input terminals 102a. The input conductive wires 103a are provided on the tape carrier base 101. The output wire section 103B includes output conductive wires 103b connected to the output terminals 102b. The output conductive wires 103b are provided on the tape carrier base 101.

As shown in FIG. 11, an input lead section 104A includes input inner leads 104a connected to the input conductive wires 103a. The input inner leads 104a are provided so as to protrude into the device hole 106. An output lead section 104B includes output inner leads 104b connected to the output conductive wires 103b. The output inner leads 104b are provided so as to protrude into the device hole 106.

As shown in FIG. 11, the insulating film 105 is provided on the tape carrier base 101 so as to cover the input and output conductive wires 103a and 103b.

As shown in FIG. 11, terminals (not shown) formed on the upper surface of the semiconductor element 108 and the input inner leads 104a are electrically connected to each other with protruding electrodes 109 therebetween. Terminals formed on the upper surface of the semiconductor element 108 and the output inner leads 104b are electrically connected to each other with the protruding electrodes 109 therebetween.

As shown in FIG. 11, the terminal formation surface (upper surface) of the semiconductor element 108, the protruding electrodes 109 and the input and output inner leads 104a and 104b are covered with an encapsulation resin 110.

As shown in FIG. 10, the semiconductor element 108 placed in the device hole 106 is fitted into a depressed portion of the metal plate 111. As shown in FIGS. 13 and 14 to be discussed later, the metal plate 111 is provided around the device hole 106 on the reverse surface (the surface opposite to the surface on which the input and output conductive wires 103a and 103b are formed) of tape carrier base 101. The metal plate 111 includes a depressed portion into which the semiconductor element 108 is fitted, and a threaded hole (see 112 in FIG. 14) into which a screw (see 117 in FIGS. 13 and 14) is screwed.

A panel with a conventional semiconductor device mounted thereon will now be described with reference to FIGS. 12-14. A specific example will be described in which a plasma display panel (PDP) is used, for example, as the panel. FIG. 12 is a perspective view showing a configuration of a PDP panel with a conventional semiconductor device mounted thereon. FIG. 13 is an enlarged perspective view showing a configuration of the PDP panel with a conventional semiconductor device mounted thereon. Specifically, FIG. 13 is an enlarged view of the area k shown in FIG. 12. FIG. 14 is a view as seen from the XIV direction shown in FIG. 13.

As shown in FIGS. 12 and 13, the PDP panel includes a glass panel 113, and a chassis 114 attached to the rear surface of the glass panel 113 with a heat dissipating sheet (not shown; see 118 in FIG. 14) therebetween. As shown in FIG. 14, the chassis 114 includes a protruding portion 115 with a threaded hole 116 therein into which a screw 117 is screwed.

As shown in FIG. 13, the semiconductor device is fixed to the glass panel 113 and to the chassis 114 with the flexible tape carrier substrate bent in a curved shape in the second direction L (i.e., the direction in which the slits 107 extend). The side of the semiconductor device closer to the output terminal section 102B is fixed to the glass panel 113, and the other side thereof closer to the input terminal section 102A is fixed to the chassis 114. Specifically, as shown in FIG. 14, the output terminal 102b is heat-pressed onto the front surface of the glass panel 113. The semiconductor device is fixed to the chassis 114 by means of the screw 117 screwed into a threaded hole 112 of the metal plate 111 where the semiconductor element 108 is fitted into the depressed portion and the threaded hole 116 of the protruding portion 115 of the chassis 114.

The PDP panel with the semiconductor device mounted thereon is accommodated in a casing (not shown).

As described above, the semiconductor device is mounted on the PDP panel with the flexible tape carrier substrate bent in a curved shape in the second direction L. In this case, there is a stress acting in the first direction W in addition to the stress acting in the second direction L (i.e., the bending direction). In order to relax these stresses, the tape carrier base 101 is provided with a plurality of slits 107 (see, for example, Japanese Patent No. 4121935 and Japanese Laid-Open Patent Publication No. 2008-298828).

### SUMMARY

However, a semiconductor device with a conventional tape carrier substrate has a problem as follows. This problem will be described with reference to FIGS. 15, 16 and 17A-17B. FIG. 15 is a perspective view showing the problem of the conventional semiconductor device mounted on a PDP panel. FIG. 16 is an enlarged perspective view showing the problem of the conventional semiconductor device mounted on a PDP panel. Specifically, FIG. 16 is an enlarged view of the area k shown in FIG. 15. FIG. 17A is an enlarged perspective view showing a state before the tape carrier substrate is stressed (displaced). On the other hand, FIG. 17B is an enlarged perspective view showing a state after the tape carrier substrate is stressed (displaced).

A PDP with a semiconductor device mounted thereon undergoes a very large temperature change inside the casing when the power is turned ON/OFF. Due to the heat, the glass panel 113 and the chassis 114 thermally expand in the direction shown in FIG. 15. Since the glass panel 113 and the chassis 114 are made of different materials, the glass panel 113 and the chassis 114 have different coefficients of thermal expansion. Thus, there is a thermal expansion difference between the glass panel 113 and the chassis 114 as shown in FIG. 16. For example, with a PDP whose screen size is 65-inch, the thermal expansion difference between the chassis 114 and the glass panel 113 is about 0.6 mm, which is very large.

The semiconductor device is fixed to the glass panel 113 and to the chassis 114 while bridging between the glass panel 113 and the chassis 114. Therefore, if there is a thermal expansion difference between the glass panel 113 and the chassis 114, the tape carrier substrate is stressed. This stress acts in the first direction W (i.e., the direction in which the plurality of slits 107 are arranged with one another).

As shown in FIG. 17B, if the tape carrier substrate is stressed in the first direction W, the tape carrier substrate warps due to the stress. The warping produces a stress on the tape carrier substrate, and the produced stress is concentrated around the slits 107. Therefore, as the power of the PDP is turned ON/OFF repeatedly (in other words, as the PDP undergoes repeated temperature changes), the output conductive wires 103b around the slits 107 may break.

Particularly, the current trend in the flat panel display market is to increase the screen size. Accordingly, the size of the glass panel 113 and the chassis 114 has also been increased. As the size of these components increases, the thermal expansion difference occurring between the glass panel 113 and the chassis 114 is very large, and the stress acting upon the tape carrier substrate is also very large. Therefore, the breaking of the output conductive wires 103b around the slits 107 may possibly occur very significantly.

Also currently in the flat panel display market, the thickness has been reduced. Accordingly, the thickness of the glass panel 113 and the chassis 114 has been reduced. As the thickness of these components decreases, the length over which the tape carrier substrate bridges between the glass panel 113 and the chassis 114 is very small, and therefore the stress acting upon the tape carrier substrate due to the warping of the tape carrier substrate is very large. Therefore, the breaking of the output conductive wires 103b around the slits 107 may possibly occur very significantly.

In view of the foregoing, it is an object of the present invention to prevent the output conductive wires from breaking.

In order to achieve the object set forth above, a first tape carrier substrate of the present invention includes: a tape carrier base; a first terminal section provided on one end portion of the tape carrier base and including a plurality of first terminals arranged with one another in a first direction; a second terminal section provided on the other end portion of the tape carrier base opposing the first terminal section and including a plurality of second terminals arranged with one another in the first direction; a first conductive wire provided on the tape carrier base and connected to the first terminal; and a second conductive wire provided on the tape carrier base and connected to the second terminal, wherein a plurality of slits arranged with one another in the first direction and each extending in a second direction different from the first direction are provided in the tape carrier base between the first terminal section and the second terminal section, and an interval between one of the plurality of slits placed at one end in the first direction and a corresponding end of the tape carrier base in the first direction and an interval between another one of the plurality of slits placed at the other end in the first direction and a corresponding end of the tape carrier base in the first direction are greater than an interval between adjacent ones of the plurality of slits.

With the first tape carrier substrate of the present invention, in a flat panel display (e.g., a PDP) on which a semiconductor device including the tape carrier substrate is mounted, even if the tape carrier substrate warps due to the stress acting in the first direction, the stress acting upon the tape carrier substrate due to the warping of the tape carrier substrate can be effectively dispersed across the entire tape carrier substrate. Therefore, it is possible to prevent the second conductive wires around the slits from breaking. Therefore, it is possible to improve the reliability of the connection between the flat panel display and the semiconductor device used as the driver therefor.

With the first tape carrier substrate of the present invention, it is preferred that a device hole is provided in the tape carrier base between the first terminal section and the second terminal section.

With the first tape carrier substrate of the present invention, it is preferred that the tape carrier substrate further includes: a first lead section including a first inner lead, wherein the first inner lead is provided so as to protrude into the device hole, and one end thereof is connected to the first conductive wire with the other end thereof electrically connected to a semiconductor element; and a second lead section including a second inner lead, wherein the second inner lead is provided so as to protrude into the device hole, and one end thereof is connected to the second conductive wire with the other end thereof electrically connected to the semiconductor element.

With the first tape carrier substrate of the present invention, it is preferred that a dimension of the slit in the first direction is 0.8 mm or more.

With the first tape carrier substrate of the present invention, it is preferred that each end portion of the slit in the second direction as viewed from above has rounded corners.

With the first tape carrier substrate of the present invention, it is preferred that the tape carrier substrate further includes a dummy wire provided on the tape carrier base around the slit.

With the first tape carrier substrate of the present invention, it is preferred that a thickness of the tape carrier base is 50 μm or less.

With the first tape carrier substrate of the present invention, it is preferred that an elasticity of the tape carrier base is 6 GPa or less.

With the first tape carrier substrate of the present invention, it is preferred that a dimension of the slit in the second direction is greater than a dimension of the slit in the first direction.

With the first tape carrier substrate of the present invention, it is preferred that the plurality of slits have an equal dimension in the second direction.

With the first tape carrier substrate of the present invention, it is preferred that the plurality of slits have an equal shape.

With the first tape carrier substrate of the present invention, it is preferred that the number of slits is at least three or more.

With the first tape carrier substrate of the present invention, it is preferred that intervals between the slits are equal to one another.

With the first tape carrier substrate of the present invention, it is preferred that the first direction and the second direction are perpendicular to each other.

With the first tape carrier substrate of the present invention, it is preferred that a semiconductor element is placed in the device hole.

With the first tape carrier substrate of the present invention, it is preferred that a metal plate is provided around the semiconductor element on the tape carrier base, the metal plate having a depressed portion into which the semiconductor element is fitted.

In order to achieve the object set forth above, a second tape carrier substrate of the present invention includes: a tape carrier base; a first terminal section provided on one end portion of the tape carrier base and including a plurality of first terminals arranged with one another in a first direction; a second terminal section provided on the other end portion of the tape carrier base and including a plurality of second terminals; a first conductive wire provided on the tape carrier base and connected to the first terminal; and a second conductive wire provided on the tape carrier base and connected to the second terminal, wherein a device hole is provided in the tape carrier base, a plurality of slits arranged with one another in the first direction and each extending in a second direction different from the first direction are provided in the tape carrier base between the first terminal section and device hole, and an interval between one of the plurality of slits placed at one end in the first direction and a corresponding end of the tape carrier base in the first direction and an interval between another one of the plurality of slits placed at the other end in the first direction and a corresponding end of the tape carrier base in the first direction are greater than an interval between adjacent ones of the plurality of slits.

With the second tape carrier substrate of the present invention, in a flat panel display (e.g., a PDP) on which a semiconductor device including the tape carrier substrate is mounted, even if the tape carrier substrate warps due to the stress acting in the first direction, the stress acting upon the tape carrier substrate due to the warping of the tape carrier substrate can be effectively dispersed across the entire tape carrier substrate. Therefore, it is possible to prevent the second conductive wires around the slits from breaking. Therefore, it is possible to improve the reliability of the connection between the flat panel display and the semiconductor device used as the driver therefor.

In order to achieve the object set forth above, a third tape carrier substrate of the present invention includes: a tape carrier base; a first terminal section provided on one end portion of the tape carrier base and including a plurality of first terminals arranged with one another in a first direction; a second terminal section provided on the other end portion of the tape carrier base and including a plurality of second terminals; a first conductive wire provided on the tape carrier base and connected to the first terminal; and a second conductive wire provided on the tape carrier base and connected to the second terminal, wherein, a plurality of slits arranged with one another in the first direction and each extending in a second direction perpendicular to the first direction are provided in the tape carrier base, and an interval between one of the plurality of slits placed at one end in the first direction and a corresponding end of the tape carrier base in the first direction and an interval between another one of the plurality of slits placed at the other end in the first direction and a corresponding end of the tape carrier base in the first direction are greater than an interval between adjacent ones of the plurality of slits.

With the third tape carrier substrate of the present invention, in a flat panel display (e.g., a PDP) on which a semiconductor device including the tape carrier substrate is mounted, even if the tape carrier substrate warps due to the stress acting in the first direction, the stress acting upon the tape carrier substrate due to the warping of the tape carrier substrate can be effectively dispersed across the entire tape carrier substrate. Therefore, it is possible to prevent the second conductive wires around the slits from breaking. Therefore, it is possible to improve the reliability of the connection between the flat panel display and the semiconductor device used as the driver therefor.

As described above, with the tape carrier substrates of the present invention, it is possible to prevent the second conductive wires from breaking.

### BRIEF DESCRIPTION OF THE DRAWINGS

FIG. 1A is a graph showing the relationship between areas and the numbers of line breaks, and FIG. 1B is a plan view showing the areas shown in FIG. 1A.

FIG. 2 is a plan view showing an observation by the present inventors.

FIG. 3 is a plan view showing a configuration of a tape carrier substrate according to an embodiment of the present invention.

FIG. 4 is a plan view showing a configuration of a semiconductor device according to an embodiment of the present invention.

FIG. 5 is a cross-sectional view showing a configuration of a semiconductor device according to an embodiment of the present invention.

FIG. 6 is a perspective view showing a configuration of a PDP panel with a semiconductor device according to an embodiment of the present invention mounted thereon.

FIG. 7 is an enlarged perspective view showing a configuration of a PDP panel with a semiconductor device according to an embodiment of the present invention mounted thereon.

FIG. 8 is a view as seen from the VIII direction shown in FIG. 7.

FIG. 9A is a graph showing the relationship between areas and the numbers of line breaks, and FIG. 9B is a plan view showing the areas shown in FIG. 9A.

FIG. 10 is a plan view showing a configuration of a conventional semiconductor device.

FIG. 11 is a cross-sectional view showing a configuration of the conventional semiconductor device.

FIG. 12 is a perspective view showing a configuration of a PDP panel with a conventional semiconductor device mounted thereon.

FIG. 13 is an enlarged perspective view showing a configuration of the PDP panel with a conventional semiconductor device mounted thereon.

FIG. 14 is a view as seen from the XIV direction shown in FIG. 13.

FIG. 15 is a perspective view showing the problem of the conventional semiconductor device mounted on a PDP panel.

FIG. 16 is an enlarged perspective view showing the problem of the conventional semiconductor device mounted on a PDP panel.

FIG. 17A is an enlarged perspective view showing a state before the tape carrier substrate is stressed (displaced). On the other hand, FIG. 17B is an enlarged perspective view showing a state after the tape carrier substrate is stressed (displaced).

### DETAILED DESCRIPTION

As a result of in-depth researches on the problem (i.e., the problem that output conductive wires around the slits break), the present inventors arrived at the following findings.

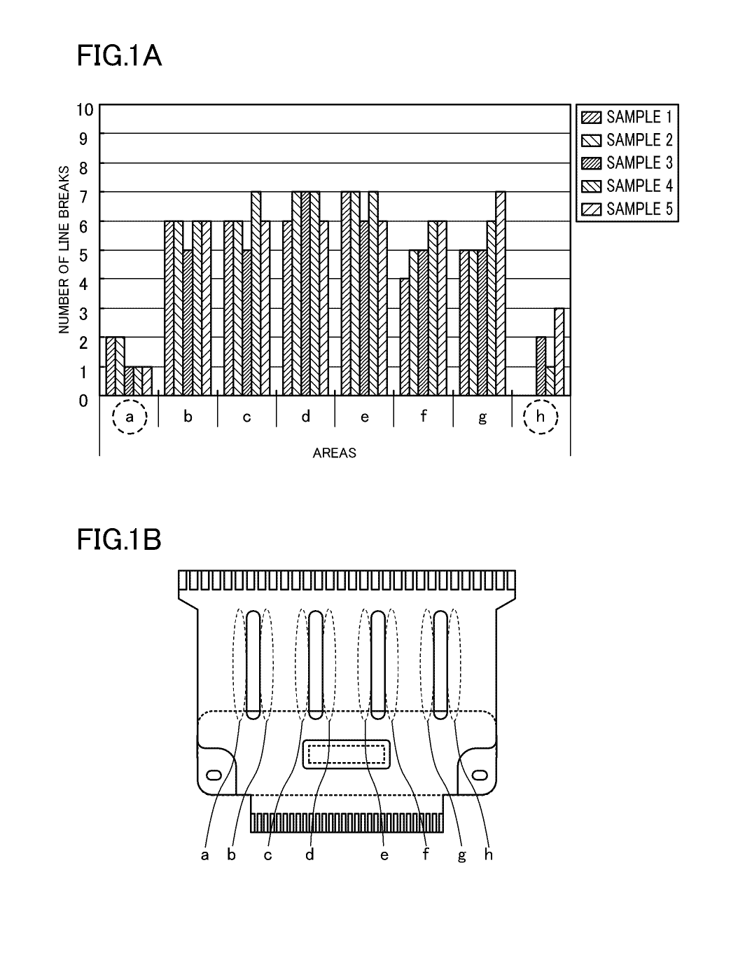

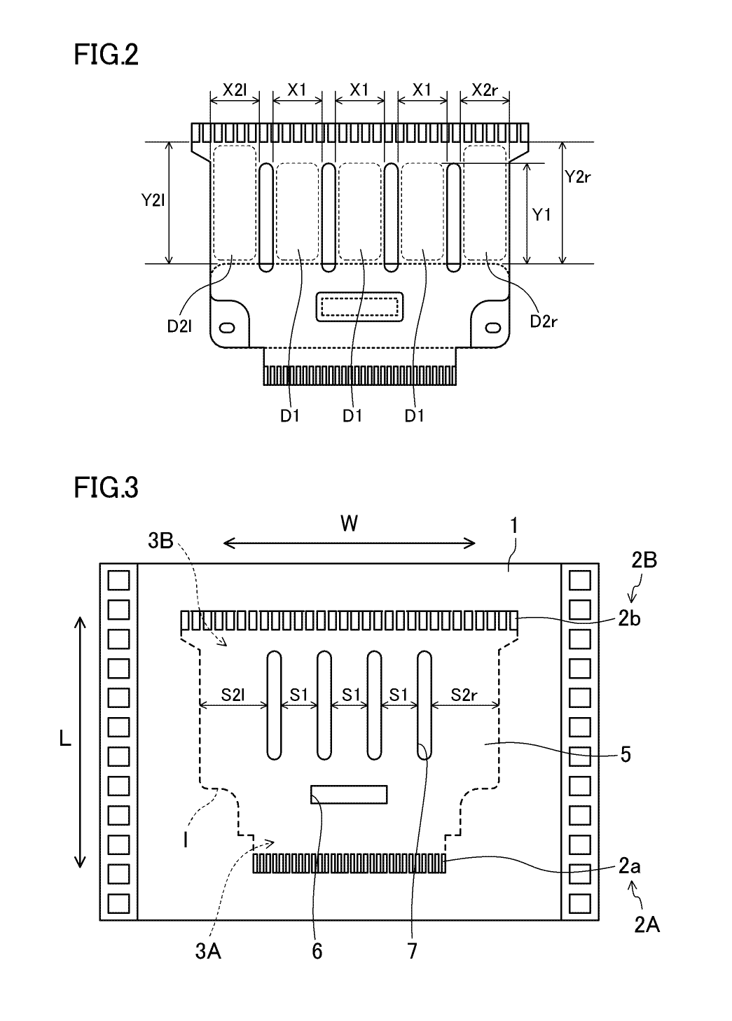

The following evaluation was conducted using PDPs with conventional semiconductor devices mounted thereon. This evaluation will be described with reference to FIGS. 1A-1B and 2. FIG. 1A is a graph showing the relationship between areas and the numbers of line breaks. FIG. 1B is a plan view showing the areas shown in FIG. 1A. FIG. 2 is a plan view showing an observation by the present inventors.

The areas A-H along the horizontal axis of FIG. 1A represent the areas A-H shown in FIG. 1B.

Five samples of PDPs with conventional semiconductor devices mounted thereon were prepared. For the areas A-H of each of the five samples 1-5, the number of output conductive wires that broke was examined.

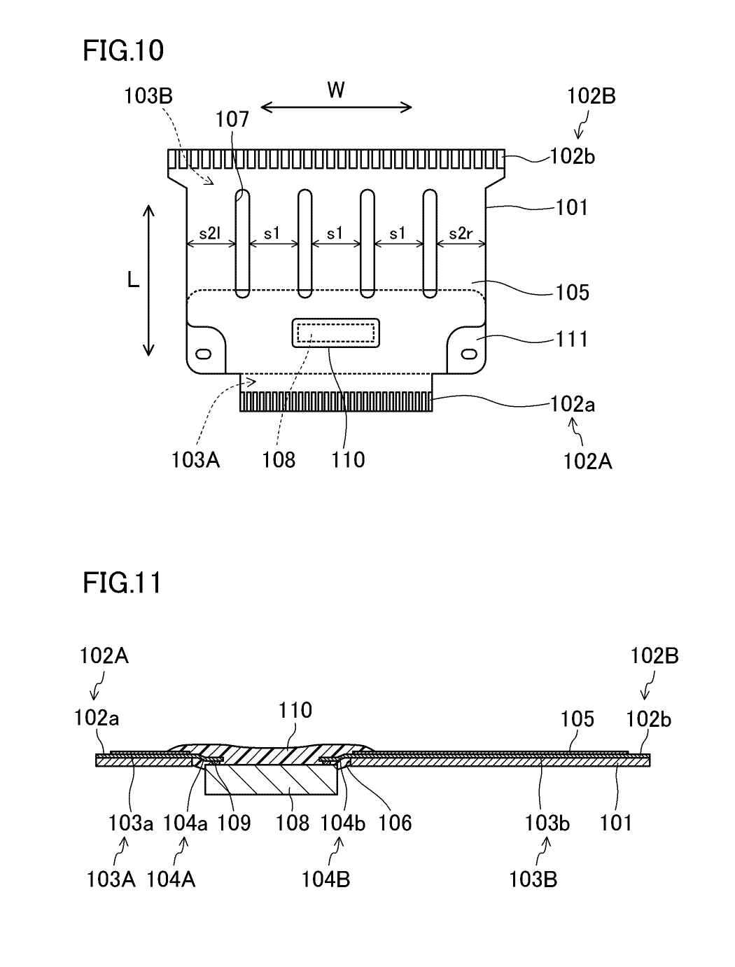

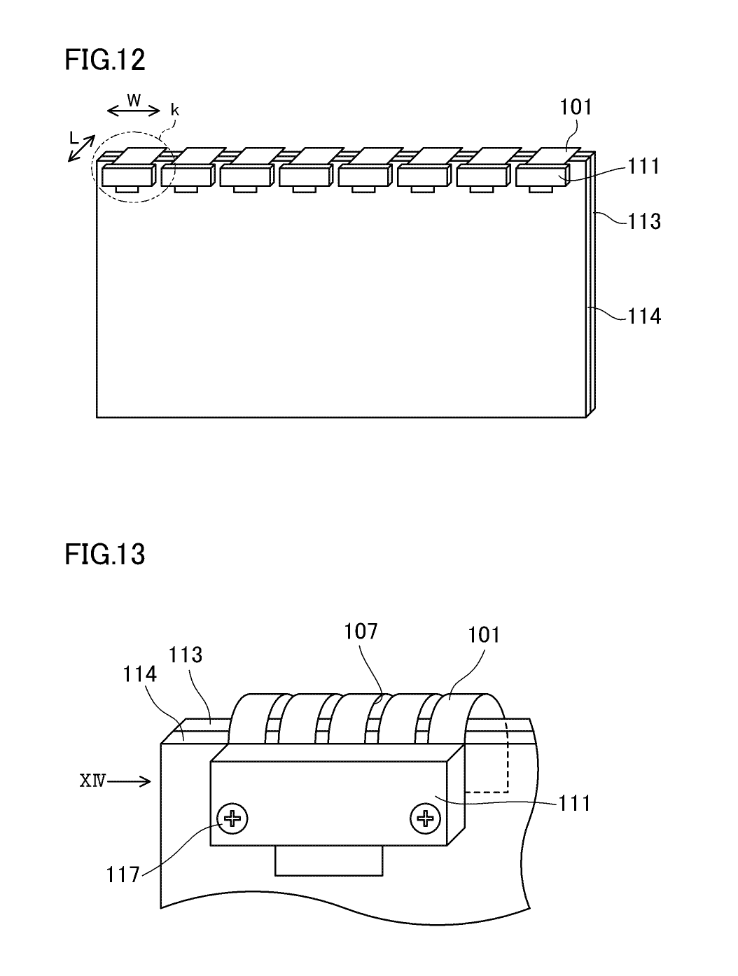

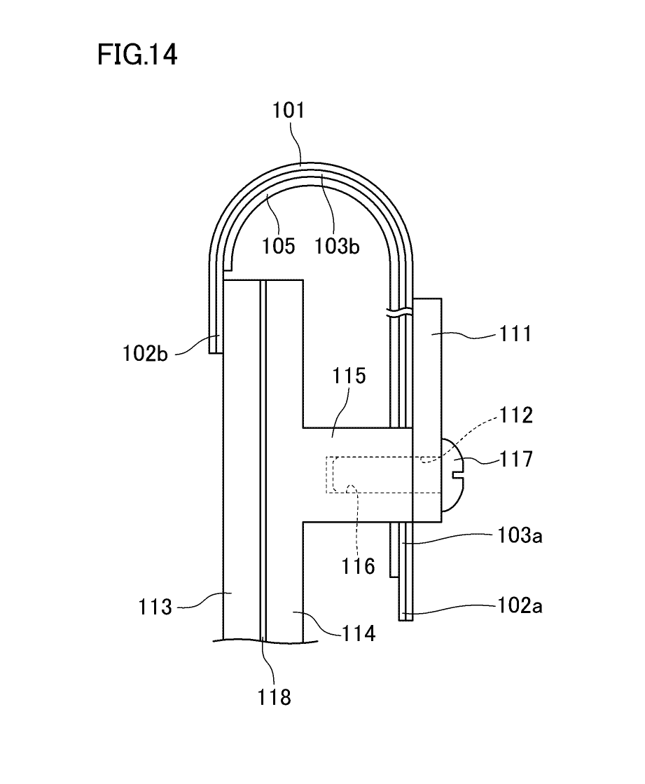

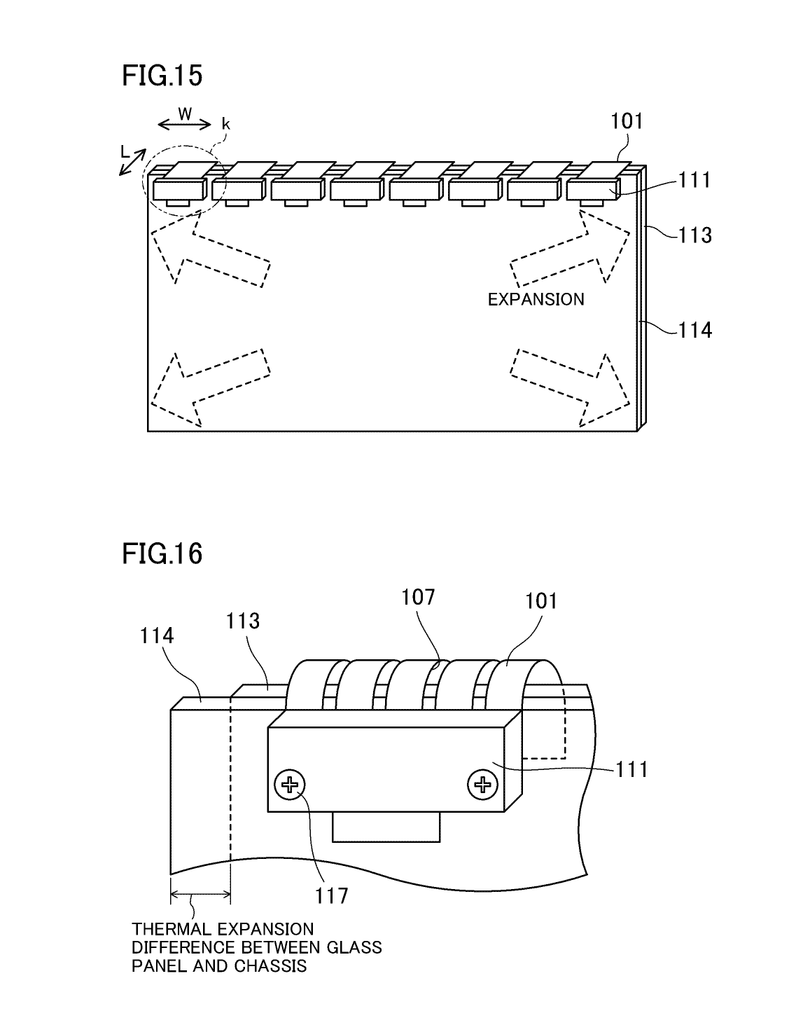

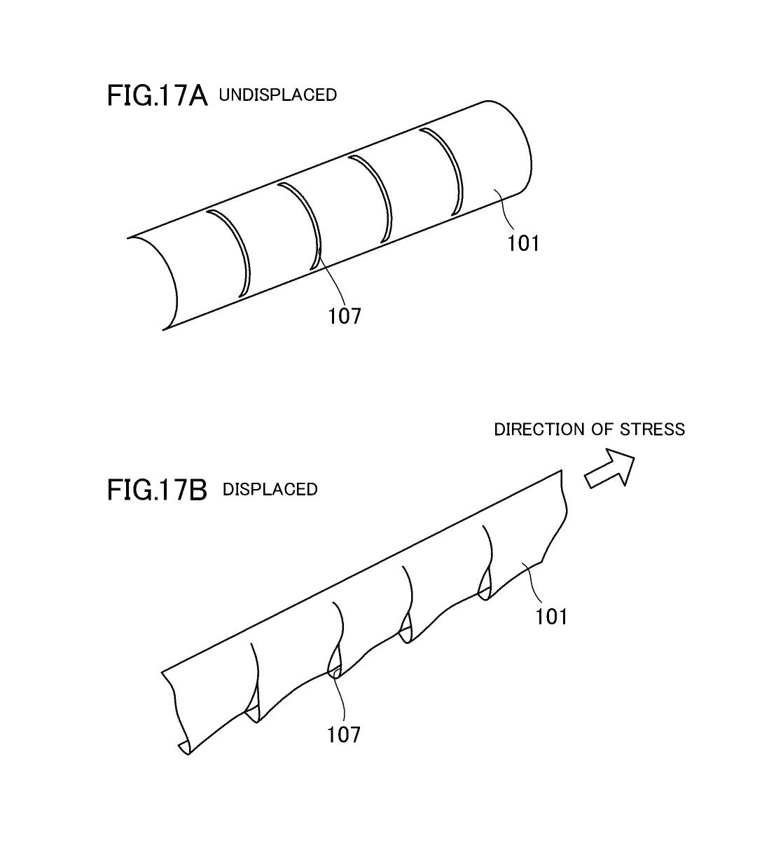

The plurality of slits 107 are arranged so that the intervals s21 and s2r and the interval s1 are equal to one another (s21=s2r=s1) as shown in FIG. 10.

As shown in FIG. 1A, the numbers of line breaks in the areas b-g are greater than those in the areas a and h. Thus, the present inventors found that the numbers of line breaks around slits 107 other than those at opposite ends are greater than the numbers of line breaks around those slits 107 at opposite ends.

It is believed that the numbers of line breaks in the areas b-g are greater than the numbers of line breaks in the areas a and h because the length Y1 of the deformable region D1 is shorter than the lengths Y21 and Y2r of the deformable regions D21 and D2r as shown in

FIG. 2. The deformable region D1 is a rectangular region having a length Y1 and a width X1 as viewed from above. The deformable region D21 is a rectangular region having a length Y21 and a width X21 as viewed from above. The deformable region D2r is a rectangular region having a length Y2r and a width X2r as viewed from above. The length Y1 refers to the length from one end of the slit 107 to the metal plate 111. The length Y21 or Y2r refers to the length from the output terminal section 102B to the metal plate 111. The length Y21 or Y2r is greater than the length Y1 (Y21>Y1, Y2r>Y1). The length Y21 and the length Y2r are equal to each other (Y21=Y2r). The width X1 is equal to the interval s1 (X1=s1). The width X21 is equal to the interval s21 (X21=s21). The width X2r is equal to the interval s2r (X2r=s2r). The width X21 or X2r is equal to the width X1 (X21=X2r=X1).

As described above, when the tape carrier substrate is stressed in the first direction W, the tape carrier substrate warps due to the stress.

The deformable region D1 is constrained by the length Y1 against the displacement of the tape carrier substrate in the first direction W. In contrast, the deformable region D21 is constrained by the length Y1 and the length Y21 against the displacement. The deformable region D2r is constrained by the length Y1 and the length Y2r against the displacement.

The length Y21 or Y2r of the deformable region D21 or D2r is greater than the length Y1 of the deformable region D1. Thus, the deformable region D21 or D2r has a greater margin than the deformable region D1, and therefore better follows the warping due to the displacement of the tape carrier substrate in the first direction W. Therefore, the stress occurring in the deformable regions D21 and D2r can be relaxed. Thus, the numbers of line breaks in the areas a and h included in the deformable regions D21 and D2r are less the numbers of line breaks in the areas b-g included in the deformable regions D1.

As a result of further in-depth researches based on the results shown in FIG. 1, the present inventors arrived at the following findings.

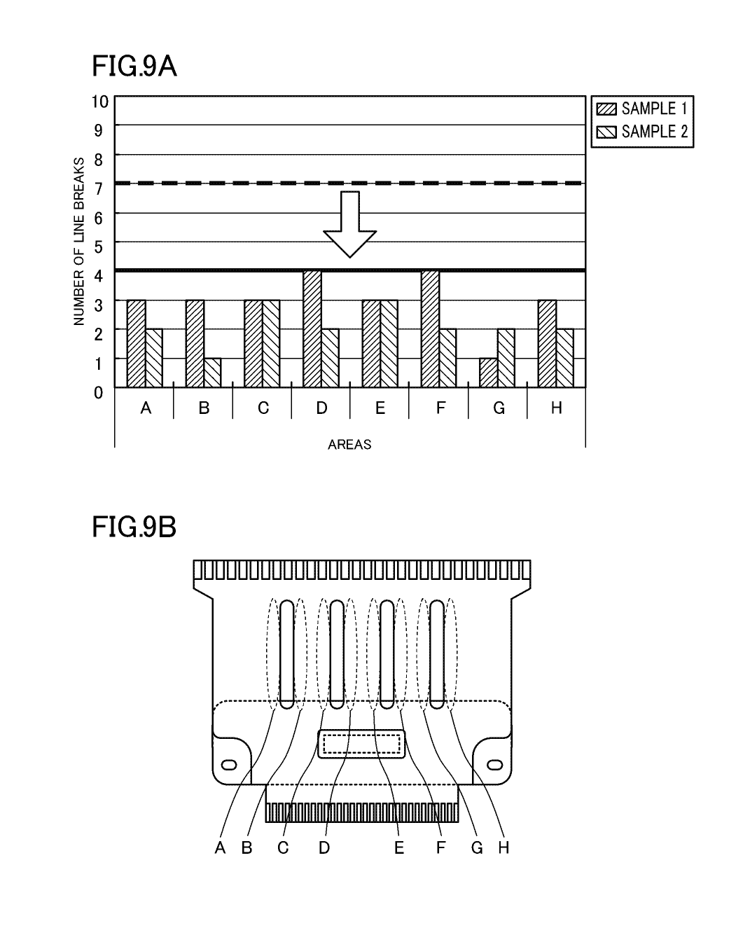

The present inventors found that by setting the interval S21 and the interval S2r to be larger than the interval S1 (S21>S1, S2r>S1) as shown in FIGS. 9A-9B to be discussed later, it is possible to effectively disperse the stress acting upon the tape carrier substrate due to the warping of the tape carrier substrate across the entire tape carrier substrate, thereby preventing output conductive wires 3b around the slits 7 from breaking. The present invention has been made based on these findings by the present inventors.

An embodiment of the present invention will now be described with reference to the drawings.

### EMBODIMENT

A tape carrier substrate according to an embodiment of the present invention will now be described with reference to FIG. 3. FIG. 3 is a plan view showing a configuration of the tape carrier substrate according to an embodiment of the present invention. Note however that the tape carrier substrate shown in FIG. 3 is a tape carrier substrate before a semiconductor element is mounted thereon as will be described later.

As shown in FIG. 3, the tape carrier substrate of the present embodiment includes a tape carrier base 1, an input terminal section 2A including input terminals 2a, an output terminal section 2B including output terminals 2b, an input wire section 3A including input conductive wires (see 3a in FIG. 5 to be discussed later), an output wire section 3B including output conductive wires (see 3b in FIG. 5 to be discussed later), an input lead section (see 4A in FIG. 5 to be discussed later) including input inner leads (see 4a in FIG. 5 to be discussed later), an output lead section (see 4B in FIG. 5 to be discussed later) including output inner leads (see 4b in FIG. 5 to be discussed later), and an insulating film 5.

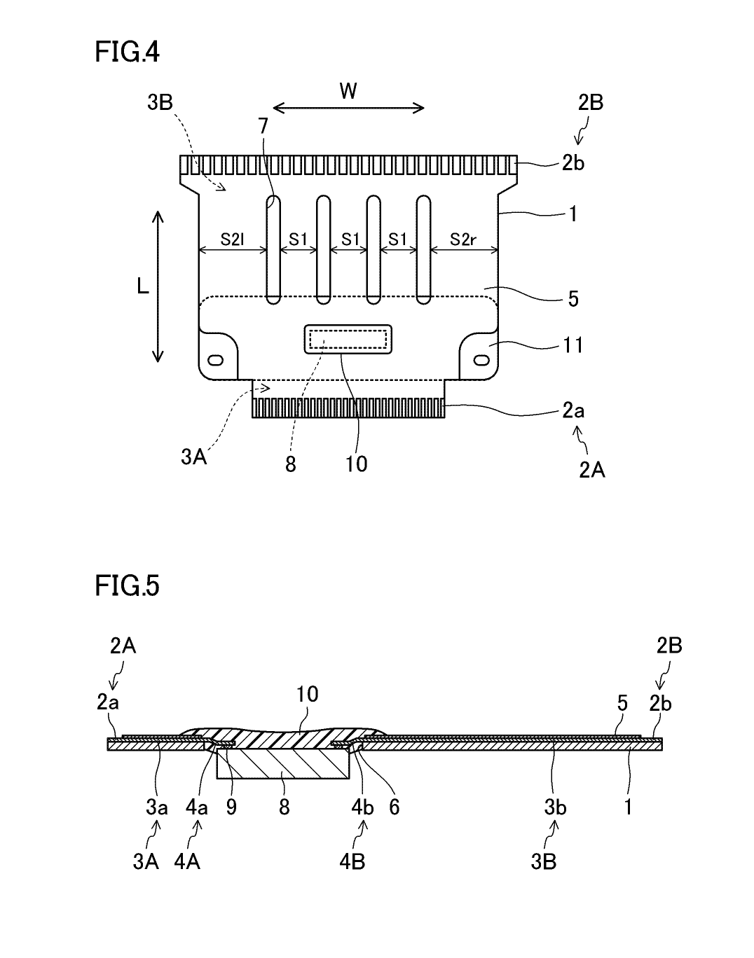

A device hole 6 is provided between the input wire section 3A and the output wire section 3B of the tape carrier base 1. A semiconductor element (see 8 in FIG. 4 to be discussed later) is placed in the device hole 6. The shape of the device hole 6 as viewed from above is similar to the shape of the semiconductor element as viewed from above, and the area thereof as viewed from above is slightly larger than the area of the semiconductor element as viewed from above. For example, where the semiconductor element has a rectangular shape as viewed from above, the device hole 6 has as rectangular shape as viewed from above. In such a case, the direction of the longer side of the rectangular shape is parallel to the first direction W (the crosswise direction of the sheet of FIG. 3).

A plurality of slits 7 are provided between the input wire section 3A and the output terminal section 2B of the tape carrier base 1 (in other words, around the output conductive wires 3b in the tape carrier base 1). The plurality of slits 7 are arranged with one another in the first direction W. Each of the plurality of slits 7 extends in the second direction L (the longitudinal direction of the sheet of FIG. 3) perpendicular to the first direction W. The dimension of the slit 7 in the second direction L is greater than the dimension of the slit 7 in the first direction W. For example, the plurality of slits 7 have the same dimension in the second direction L. For example, the plurality of slits 7 have the same dimension in the first direction W. Thus, for example, the plurality of slits 7 have the same shape. The dimension of the slit 7 in the first direction W is preferably 0.8 mm or more, for example. Each end portion of the slit 7 in the second direction L as viewed from above preferably has rounded corners, for example. Specifically, it preferably has an arc shape, for example.

The input terminal section 2A includes a plurality of input terminals 2a. The plurality of input terminals 2a are provided on the tape carrier base 1. The plurality of input terminals 2a are arranged with one another in the first direction W. The output terminal section 2B includes a plurality of output terminals 2b. The plurality of output terminals 2b are provided on the tape carrier base 1. The plurality of output terminals 2b are arranged with one another in the first direction W. The input terminal section 2A and the output terminal section 2B oppose each other in the second direction L.

The input wire section 3A includes input conductive wires (see 3a in FIG. 5 to be discussed later) connected to the input terminals 2a. A plurality of input conductive wires are provided on the tape carrier base 1. The output wire section 3B includes output conductive wires (see 3b in FIG. 5 to be discussed later) connected to the output terminals 2b. A plurality of output conductive wires are provided on the tape carrier base 1. The input conductive wires and the output conductive wires are made of copper, for example.

An input lead section 4A includes input inner leads (see 4a in FIG. 5 to be discussed later) connected to input conductive wires (see 3a in FIG. 5 to be discussed later). The input inner leads are provided so as to protrude into the device hole 6. The input inner leads are electrically connected to the semiconductor element (see 8 in FIG. 5 to be discussed later) placed in the device hole 6. An output lead section 4B includes output inner leads (see 4b in FIG. 5 to be discussed later) connected to output conductive wires (see 3b in FIG. 5 to be discussed later). The output inner leads are provided so as to protrude into the device hole 6. The output inner leads are electrically connected to the semiconductor element placed in the device hole 6.

Thus, as shown in FIG. 5 to be discussed later, one end of an input conductive wire 3a is connected to an input inner lead 4a which is electrically connected to a semiconductor element 8, with the other end thereof connected to the input terminal 2a. One end of the output conductive wire 3b is connected to an output inner lead 4b which is electrically connected to the semiconductor element 8, with the other end thereof connected to the output terminal 2b.

Preferably, the thickness of the tape carrier base 1 is 50 μm or less, for example, or the elasticity thereof is 6 GPa or less, for example.

The insulating film 5 is provided on the tape carrier base 1 so as to cover the input conductive wire 3a and the output conductive wire 3b. The insulating film 5 is made of an organic insulating material such as polyimide or epoxy, for example.

The tape carrier substrate with the semiconductor element (see 8 in FIG. 4 to be discussed later) placed in the device hole 6 is eventually punched into the shape of the tape carrier base 1 as shown in FIG. 4 to be discussed later. The dotted line shown in FIG. 3 is a punch-through line 1.

The interval S21 between the slit 7 at one end (the left end in FIG. 3) and the punch-through line 1 is greater than the interval S1 between adjacent slits 7 (S21>S1). The interval S2r between the slit 7 at the other end (the right end in FIG. 3) and the punch-through line 1 is greater than the interval S1 (S2r>S1). For example, the interval S21 and the interval S2r are equal to each other (S21=S2r). The three intervals Si shown in the figure are equal to one another, for example. The values of the intervals S21, S2r and S1 are determined based on the installed height of the semiconductor device to be attached to the panel, the dimension of the tape carrier substrate in the first direction W, the number of slits 7, etc. Specifically, the interval S21 is 9.5 mm, for example. The interval S2r is 9.5 mm, for example. The interval S1 is 8 mm, for example.

A semiconductor device according to an embodiment of the present invention will now be described with reference to FIGS. 4-5. The semiconductor device of the present embodiment is a semiconductor device including a semiconductor element mounted on a tape carrier substrate of the present embodiment. FIG. 4 is a plan view showing a configuration of a semiconductor device according to an embodiment of the present invention. FIG. 5 is a cross-sectional view showing a configuration of a semiconductor device according to an embodiment of the present invention. FIG. 5 does not show a metal plate for the sake of simplicity.

As shown in FIG. 4, the semiconductor device includes a tape carrier substrate, the semiconductor element 8, and a metal plate 11. Note however that the tape carrier substrate is a tape carrier substrate that has been punched into the tape carrier base 1 along the punch-through line 1 shown in FIG. 3, as described above.

As shown in FIG. 5, terminals (not shown) formed on the upper surface of the semiconductor element 8 and the input inner leads 4a provided so as to protrude into the device hole 6 are electrically connected to each other with protruding electrodes 9 therebetween. Terminals formed on the upper surface of the semiconductor element 8 and the output inner leads 4b provided so as to protrude into the device hole 6 are electrically connected to each other with the protruding electrodes 9 therebetween.

As shown in FIG. 5, the terminal formation surface (upper surface) of the semiconductor element 8, the protruding electrodes 9 and the input and output inner leads 4a and 4b are covered with an encapsulation resin 10.

The metal plate 11 is made of aluminum, for example. As shown in FIG. 4, the metal plate 11 is provided around the device hole 6 on the reverse surface of the tape carrier base 1. The reverse surface of the tape carrier base 1 refers to the surface opposite to the surface of the tape carrier base 1 on which the input and output conductive wires (see 3a and 3b in FIG. 5) are formed. As shown in FIG. 8 to be discussed later, the surface of the metal plate 11 to be in contact with the tape carrier base 1 is a flat surface, and an adhesive (not shown) such as a double-sided adhesive tape, for example, is provided between the tape carrier base 1 and the metal plate 11. The metal plate 11 is bonded to the tape carrier base 1 with the adhesive.

The metal plate 11 includes a depressed portion into which the semiconductor element 8 is fitted, and a threaded hole (see 12 in FIG. 8 to be discussed later) into which a screw (see 17 in FIG. 8 to be discussed later) is screwed. The depressed portion is provided on the surface of the metal plate 11 in contact with the tape carrier base 1, and the semiconductor element 8 is fitted into the depressed portion. For example, the gap between the bottom surface of the depressed portion and the reverse surface of the semiconductor element 8 (i.e., the surface of the semiconductor element 8 that is opposite to the terminal formation surface (upper surface)) is filled with a resin such as silicon or a thermally-conductive, electrically-conductive paste (not shown).

A method for manufacturing a semiconductor device according to the present embodiment will now be described.

First, a tape carrier substrate shown in FIG. 3 is prepared.

Next, the protruding electrodes 9 are provided on the terminals formed on the upper surface of the semiconductor element 8, and then the protruding electrodes 9 and the input and output inner leads 4a and 4b are heat-pressed together using a bonding tool. Note that after the protruding electrodes 9 are provided on the input and output inner leads 4a and 4b, the protruding electrode 9 and the terminals of the semiconductor element 8 may be heat-pressed together using a bonding tool.

Next, the terminal formation surface (upper surface) of the semiconductor element 8, the protruding electrodes 9 and the input and output inner leads 4a and 4b are potted with a thermosetting resin. Then, the thermosetting resin is cured by heat, thereby providing the encapsulation resin 10. Therefore, the semiconductor element 8, the protruding electrodes 9 and the input and output inner leads 4a and 4b are electrically and physically protected from adverse environmental factors such as external forces, humidity and contaminants.

Next, the tape carrier base 1 is punched through along the punch-through line 1 shown in FIG. 3.

Next, a thermally-conductive, electrically-conductive paste, for example, is applied on the bottom surface of the depressed portion of the metal plate 11. Then, the semiconductor element 8 is fitted into the depressed portion of the metal plate 11, and the tape carrier base 1 and the metal plate 11 are bonded together with an adhesive such as a double-sided adhesive tape, for example. The gap between the bottom surface of the depressed portion of the metal plate 11 and the reverse surface of the semiconductor element 8 (the surface opposite to the terminal formation surface) is filled with a conductive paste. Note that a resin may be used instead of a conductive paste. The semiconductor device of the present embodiment can be manufactured as described above.

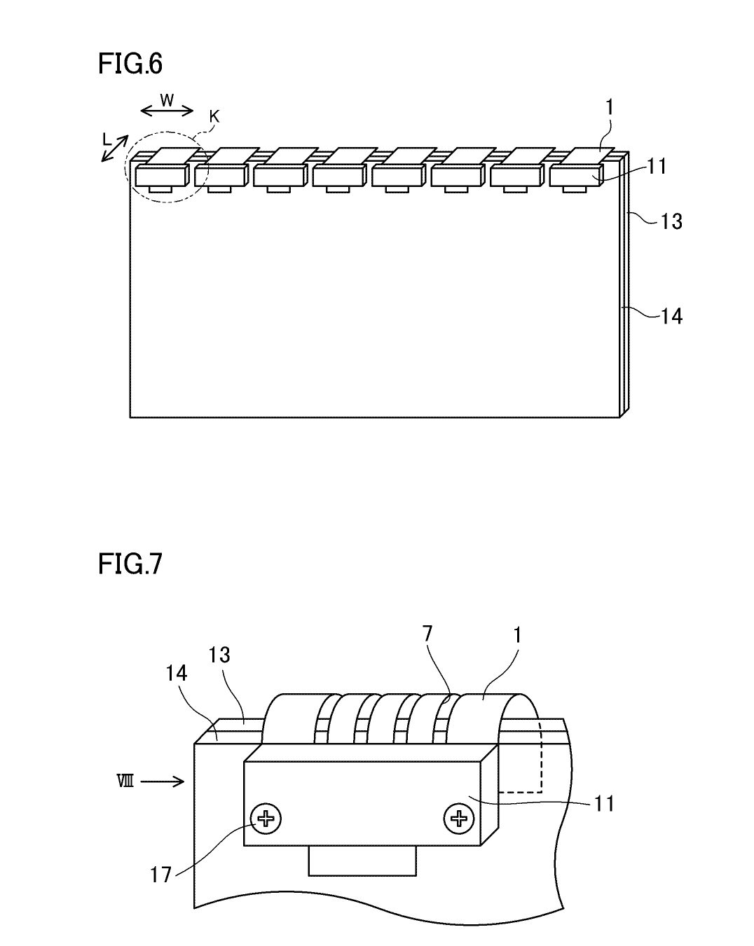

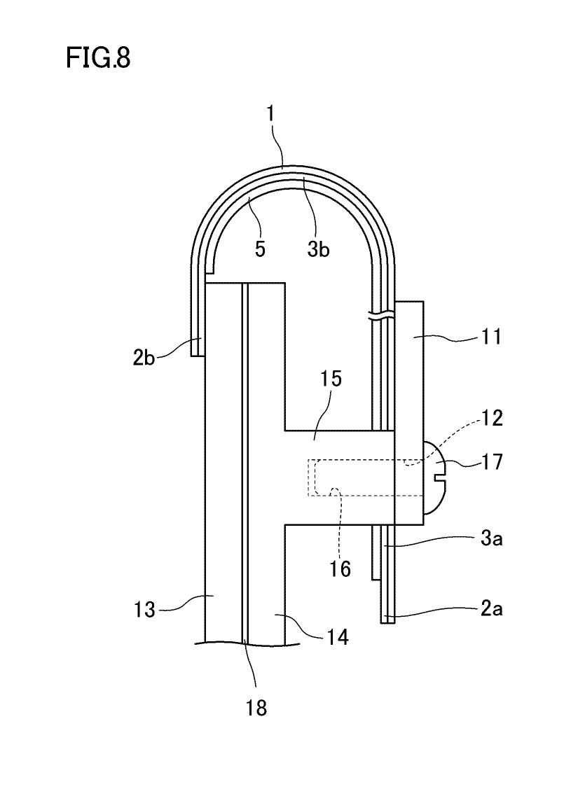

A PDP panel with a semiconductor device according to an embodiment of the present invention mounted thereon will now be described with reference to FIGS. 6-8. FIG. 6 is a perspective view showing a configuration of a PDP panel with a semiconductor device according to an embodiment of the present invention mounted thereon. FIG. 7 is an enlarged perspective view showing a configuration of a PDP panel with a semiconductor device according to an embodiment of the present invention mounted thereon. Specifically, FIG. 7 is an enlarged view of the area k shown in FIG. 6. FIG. 8 is a view as seen from the VIII direction shown in FIG. 7.

As shown in FIGS. 6 and 7, the PDP panel includes a glass panel 13, and a chassis 14 attached to the rear surface of the glass panel 13 with a heat dissipating sheet (not shown; see 18 in FIG. 8) therebetween. As shown in FIG. 8, the chassis 14 includes a protruding portion 15 with a threaded hole 16 therein into which a screw 17 is screwed.

A semiconductor device is mounted on the PDP panel. The semiconductor device mounted on the PDP panel is used as a driver, for example. As shown in FIG. 7, the semiconductor device is fixed to the glass panel 13 and to the chassis 14 with the flexible tape carrier substrate bent in a curved shape.

The tape carrier substrate is bent in the second direction L. The second direction L is the direction in which the slits 7 extend. The tape carrier substrate is bent with the side of the input and output conductive wires 3a and 3b facing in (in other words, with the side of the metal plate 11 facing out).

One side of the semiconductor device that is closer to the output terminal section 2B is fixed to the front surface of the glass panel 13. Specifically, as shown in FIG. 8, the output terminals 2b of the semiconductor device are heat-pressed onto the front surface of the glass panel 13 with an anisotropic conductive film (ACF), for example. Thus, the output conductive wires 3b connected to the output terminals 2b are electrically connected to the glass panel 13.

On the other hand, one side of the semiconductor device that is closer to the input terminal section 2A is fixed to the chassis 14. Specifically, as shown in FIG. 8, one side of the semiconductor device that is closer to the input terminal section 2A is fixed to the chassis 14 with the screw 17 which is screwed through a threaded hole 12 of the metal plate 11 and the threaded hole 16 of the protruding portion 15 of the chassis 14. By bringing the metal plate 11 made of aluminum, for example, into contact with the protruding portion 15 of the chassis 14, heat from the semiconductor element 8 fitted into the depressed portion of the metal plate 11 can be dissipated into the chassis 14.

The glass panel 13 is a glass plate. One side of the semiconductor device that is closer to the output terminal section 2B is fixed to the front surface of the glass panel 13 as described above. As shown in FIG. 6, the chassis 14 having substantially the same size as the glass panel 13 is attached to the rear surface of the glass panel 13 with a heat dissipating sheet (see 18 in FIG. 8) therebetween. A heat dissipating sheet is provided between the glass panel 13 and the chassis 14 because the amount of heat generated from the panel and peripheral components such as the power supply is very large with recent PDPs due to the high voltage operation.

As shown in FIG. 8, the chassis 14 includes the protruding portion 15 provided on one surface opposite to the surface in contact with a heat dissipating sheet 18. The threaded hole 16 is provided in the protruding portion 15. As described above, one side of the semiconductor device that is closer to the input terminal section 2A is fixed to the chassis 14. The chassis 14 plays a central role for outputting a video image to the PDP panel. A power supply circuit and a signal control circuit board (not shown) are attached to the chassis 14.

The PDP panel with the semiconductor device mounted thereon is accommodated in a casing (not shown). Thus, the semiconductor device is accommodated in a narrow gap between the glass panel 13 and the chassis 14 and the casing.

A method for mounting a semiconductor device of the present embodiment on a PDP panel will now be described.

First, the output terminal 2b is heat-pressed onto the front surface of the glass panel 13 with an ACF, for example. Thus, one side of the semiconductor device that is closer to the output terminal section 2B is fixed to the glass panel 13.

Next, the tape carrier substrate is bent in a curved shape in the second direction L with the side of the metal plate 11 facing out. The tape carrier substrate is bent so that the threaded hole 12 provided in the metal plate 11 and the threaded hole 16 provided in the protruding portion 15 of the chassis 14 are aligned with each other.

Next, the screw 17 is screwed through the threaded hole 12 of the metal plate 11 and the threaded hole 16 of the protruding portion 15. Thus, one side of the semiconductor device that is closer to the input terminal section 2A is fixed to the chassis 14.

The semiconductor device of the present embodiment can be mounted on a PDP panel as described above. The PDP panel with the semiconductor device mounted thereon is accommodated in a casing.

The following evaluation was conducted using PDPs with semiconductor devices according to an embodiment of the present invention mounted thereon. This evaluation will be described with reference to FIGS. 9A-9B. FIG. 9A is a graph showing the relationship between areas and the numbers of line breaks. FIG. 9B is a plan view showing the areas shown in FIG. 9A.

The areas A-H along the horizontal axis of FIG. 9A represent the areas A-H shown in FIG. 9B.

Two samples of PDPs with semiconductor devices according to an embodiment of the present invention mounted thereon were prepared. For the areas A-H of each of the two samples 1-2, the number of output conductive wires that broke was examined.

A comparison between the results shown in FIG. 1A (the results for PDPs with conventional semiconductor devices mounted thereon) and those shown in FIG. 9A shows that the number of line breaks is reduced in the present embodiment to about ½ that with the conventional samples. As can be seen from this, by setting the intervals S21 and S2r to be greater than the interval S1, it is possible to effectively disperse the stress acting upon the tape carrier substrate due to the warping of the tape carrier substrate across the entire tape carrier substrate.

According to the present embodiment, the intervals S21 and S2r are set to be greater than the interval S1. Thus, in a PDP with a semiconductor device of the present embodiment mounted thereon, even if the tape carrier substrate warps due to the stress acting in the first direction W, it is possible to effectively disperse the stress acting upon the tape carrier substrate due to the warping of the tape carrier substrate across the entire tape carrier substrate. Therefore, it is possible to prevent the output conductive wires 3b around the slits 7 from breaking. Thus, it is possible to improve the reliability of the connection between the PDP and the semiconductor device used as the driver therefor.

In addition, according to the present embodiment, the dimension of the plurality of slits 7 in the first direction W is 0.8 mm or more, for example. Then, the stress acting upon tape carrier substrate due to the warping of the tape carrier substrate can be prevented from being concentrated around the slits 7 (particularly, the opposite ends of the slits 7 in the second direction L) and breaking the tape carrier base 1.

Moreover, according to the present embodiment, each end portion of the slit 7 in the second direction L as viewed from above has rounded corners, for example. Then, the stress acting upon tape carrier substrate due to the warping of the tape carrier substrate can be prevented from being concentrated around the slits 7 (particularly, the opposite ends of the slits 7 in the second direction L) and breaking the tape carrier base 1.

Moreover, according to the present embodiment, the thickness of the tape carrier base 1 is set to 50 μm or less, for example, or the elasticity of the tape carrier base 1 is set to 6 GPa or less, for example. Then, the stress acting upon the tape carrier substrate due to the warping of the tape carrier substrate can be dispersed across the entire tape carrier substrate. Thus, it is possible to more reliably prevent the output conductive wires 3b around the slits 7 from breaking.

Note that while the present embodiment is directed to a specific example where the interval S21 and the interval S2r are equal to each other (S21=S2r), for example, as shown in FIG. 4, the present invention is not limited thereto. First, for example, the interval S21 may be less than the interval S2r (S21<S2r). Second, for example, the interval S21 may be greater than the interval S2r (S21>S2r). It is only required that the intervals S21 and S2r are greater than the interval S1 (S21>S1, S2r>S1).

While the present embodiment is directed to a specific example where the three intervals S1 illustrated in the figures are equal to one another, as shown in FIG. 4, the present invention is not limited thereto. For example, the intervals 5 1 may be different from one another. It is only required that the intervals S1, which are different from one another, are all less than the intervals S21 and S2r.

While the present embodiment is directed to a specific example where the first direction W in which the input terminals 2a are arranged with one another and the second direction L in which the slits 7 extend are perpendicular to each other for example (in other words, where the angle at which the first direction W and the second direction L cross each other is 90°, for example), the present invention is not limited thereto. It is only required that the first direction and the second direction are different from each other. For example, the angle at which the first direction and the second direction cross each other is preferably 90°±2°.

While the present embodiment is directed to a specific example where the output terminal section 2B opposes the input terminal section 2A, and the direction in which the output terminals 2b are arranged with one another is equal to the direction in which the input terminals 2a are arranged with one another (i.e., the first direction W), the present invention is not limited thereto. For example, the direction in which the input terminals 2a are arranged with one another and the direction in which the output terminals 2b are arranged with one another may be different from each other. It is only required that the input terminal section 2A is provided on one end portion of the tape carrier base 1, while the output terminal section 2B is provided on the other end portion of the tape carrier base 1.

While the present embodiment is directed to a specific example where the number of slits 7 is four, for example, as shown in FIGS. 3 and 4, the present invention is not limited thereto. It is only required that the number of slits 7 is at least three or more.

While the present embodiment is directed to a specific example where the semiconductor device is a TCP (a semiconductor device with the semiconductor element 8 mounted in the device hole provided in the wiring circuit board), the present invention is not limited thereto. For example, a COP (Chip On Film) may be used. Also in such a case, it is possible to obtain similar effects to those of the present embodiment. With a COP, a semiconductor element can be mounted directly onto a wiring circuit board without providing a device hole.

While the present embodiment is directed to a specific example where the end portions of the slits 7 in the second direction L have an arc shape, for example, as viewed from above, the present invention is not limited thereto.

### VARIATION OF EMBODIMENT

A plurality of dummy wires are provided around the slits on the tape carrier base.

Then, even if the stress acting upon the tape carrier substrate due to the warping of the tape carrier substrate is concentrated around the slits, the dummy wires break, and it is possible to prevent the output conductive wires from breaking.

Note that the present invention is not limited to embodiments described above and variations thereof, and various modifications can be made thereto without departing from the spirit of the present invention.

Note that the present invention, capable of preventing output conductive wires from breaking, as described above, is useful as a tape carrier substrate.

What is claimed is:

1. A tape carrier substrate comprising:
a tape carrier base;
a first terminal section provided on one end portion of the tape carrier base and including a plurality of first terminals arranged with one another in a first direction;
a second terminal section provided on the other end portion of the tape carrier base opposing the first terminal section and including a plurality of second terminals arranged with one another in the first direction;
a first conductive wire provided on the tape carrier base and connected to the first terminal; and
a second conductive wire provided on the tape carrier base and connected to the second terminal, wherein
a plurality of slits arranged with one another in the first direction and each extending in a second direction different from the first direction are provided in the tape carrier base between the first terminal section and the second terminal section, and
an interval between one of the plurality of slits placed at one end in the first direction and a corresponding end of the tape carrier base in the first direction and an interval between another one of the plurality of slits placed at the other end in the first direction and a corresponding end of the tape carrier base in the first direction are greater than an interval between adjacent ones of the plurality of slits.

2. The tape carrier substrate of claim 1, wherein
a device hole is provided in the tape carrier base between the first terminal section and the second terminal section.

3. The tape carrier substrate of claim 2, further comprising:
a first lead section including a first inner lead, wherein the first inner lead is provided so as to protrude into the device hole, and one end thereof is connected to the first conductive wire with the other end thereof electrically connected to a semiconductor element; and
a second lead section including a second inner lead, wherein the second inner lead is provided so as to protrude into the device hole, and one end thereof is connected to the second conductive wire with the other end thereof electrically connected to the semiconductor element.

4. The tape carrier substrate of claim 1, wherein
a dimension of the slit in the first direction is 0.8 mm or more.

5. The tape carrier substrate of claim 1, wherein
each end portion of the slit in the second direction as viewed from above has rounded corners.

6. The tape carrier substrate of claim 1, further comprising:
a dummy wire provided on the tape carrier base around the slit.

7. The tape carrier substrate of claim 1, wherein a thickness of the tape carrier base is 50 μm or less.

8. The tape carrier substrate of claim 1, wherein
an elasticity of the tape carrier base is 6 GPa or less.

9. The tape carrier substrate of claim 1, wherein
a dimension of the slit in the second direction is greater than a dimension of the slit in the first direction.

10. The tape carrier substrate of claim 1, wherein
the plurality of slits have an equal dimension in the second direction.

11. The tape carrier substrate of claim 1, wherein
the plurality of slits have an equal shape.

12. The tape carrier substrate of claim 1, wherein
the number of slits is at least three or more.

13. The tape carrier substrate of claim 12, wherein
intervals between the slits are equal to one another.

14. The tape carrier substrate of claim 1, wherein
the first direction and the second direction are perpendicular to each other.

15. The tape carrier substrate of claim 2, wherein
a semiconductor element is placed in the device hole.

16. The semiconductor device of claim 15, wherein
a metal plate is provided around the semiconductor element on the tape carrier base, the metal plate having a depressed portion into which the semiconductor element is fitted.

17. A tape carrier substrate comprising:
a tape carrier base;
a first terminal section provided on one end portion of the tape carrier base and including a plurality of first terminals arranged with one another in a first direction;
a second terminal section provided on the other end portion of the tape carrier base and including a plurality of second terminals;
a first conductive wire provided on the tape carrier base and connected to the first terminal; and
a second conductive wire provided on the tape carrier base and connected to the second terminal, wherein
a device hole is provided in the tape carrier base,
a plurality of slits arranged with one another in the first direction and each extending in a second direction different from the first direction are provided in the tape carrier base between the first terminal section and the device hole, and
an interval between one of the plurality of slits placed at one end in the first direction and a corresponding end of the tape carrier base in the first direction and an interval between another one of the plurality of slits placed at the other end in the first direction and a corresponding end of the tape carrier base in the first direction are greater than an interval between adjacent ones of the plurality of slits.

18. A tape carrier substrate comprising:
a tape carrier base;
a first terminal section provided on one end portion of the tape carrier base and including a plurality of first terminals arranged with one another in a first direction;
a second terminal section provided on the other end portion of the tape carrier base and including a plurality of second terminals;
a first conductive wire provided on the tape carrier base and connected to the first terminal; and
a second conductive wire provided on the tape carrier base and connected to the second terminal, wherein,
a plurality of slits arranged with one another in the first direction and each extending in a second direction perpendicular to the first direction are provided in the tape carrier base, and
an interval between one of the plurality of slits placed at one end in the first direction and a corresponding end of the tape carrier base in the first direction and an interval between another one of the plurality of slits placed at the other end in the first direction and a corresponding end of the tape carrier base in the first direction are greater than an interval between adjacent ones of the plurality of slits.
